(19) United States
(12) Patent Application Publication
(10) Pub. No.: US 2026/0194395 A1
(43) Pub. Date: Jul. 9, 2026

(54) ELECTRICAL CONNECTION UNIT

(71) Applicant: Yazaki Corporation, Tokyo (JP)

(72) Inventor: Hirotaka MUKASA, Kakegawa-shi (JP)

(73) Assignee: Yazaki Corporation, Tokyo (JP)

(21) Appl. No.: 19/414,904

(22) Filed: Dec. 10, 2025

(30) Foreign Application Priority Data
Jan. 6, 2025 (JP) 2025-000769

(51) Int. Cl. G01K 1/14; H01R 4/30; H01R 4/34

(52) U.S. Cl. CPC G01K 1/14; H01R 4/308; H01R 4/34

(57) ABSTRACT

An electrical connection unit according to an embodiment includes: a wiring member; a connection target component to which the wiring member is electrically connected; a fastening member that comes into contact with the wiring member and fixes the wiring member to the connection target component; and a temperature detector that is attached to the fastening member and detects a temperature.

### BACKGROUND OF THE INVENTION

### Field Of the Invention

Embodiments of the present invention relate to an electrical connection unit.

Priority is claimed on Japanese Patent Application No. 2025-000769 filed in Japan on January 6, 2025, the content of which is incorporated herein by reference.

### Description of Related Art

As one of in-vehicle devices, an electrical connection unit including an electronic component and a bus bar connected to the electronic component is used.

### Prior art document

### Patent document

Patent Document 1: PCT International Publication No. WO2021/059767

### SUMMARY OF THE INVENTION

With the increase in current of the electrical connection unit, it is desired to easily measure a temperature of a portion where a wiring member and a connection target component are connected.

An embodiment provides an electrical connection unit capable of easily measuring a temperature of a portion where a wiring member and a connection target component are connected.

An electrical connection unit according to an embodiment includes: a wiring member; a connection target component to which the wiring member is electrically connected; a fastening member that comes into contact with the wiring member and fixes the wiring member to the connection target component; and a temperature detector that is attached to the fastening member and detects a temperature.

According to one embodiment, it is possible to easily measure a temperature of a portion where a wiring member and a connection target component are connected.

### BRIEF DESCRIPTION OF THE DRAWINGS

FIG. 1 is a cross-sectional view illustrating an electrical connection unit 1 according to a first embodiment.

FIG. 2 is a perspective view illustrating a part of the electrical connection unit 1.

FIG. 3 is an exploded perspective view of a part of the electrical connection unit 1.

FIG. 4 is a plan view illustrating a first electronic component 20 and a metal component.

FIG. 5 is a cross-sectional view for explaining a method of manufacturing the electrical connection unit 1.

FIG. 6 is a cross-sectional view for explaining the method of manufacturing the electrical connection unit 1.

FIG. 7 is a cross-sectional view for explaining the method of manufacturing the electrical connection unit 1.

FIG. 8 is a cross-sectional view illustrating an electronic component, a metal component, a bus bar, and a fastening member according to a second embodiment.

FIG. 9 is a cross-sectional view illustrating an electronic component, a bus bar, and a fastening member according to a third embodiment.

FIG. 10 is a cross-sectional view illustrating an electronic component, a metal component, a bus bar, and a fastening member according to a fourth embodiment.

FIG. 11 is a cross-sectional view illustrating an electronic component, a bus bar, and a fastening member according to a fifth embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. “Parallel”, “orthogonal”, or “the same” may include “substantially parallel”, “substantially orthogonal”, or “substantially the same”, respectively.

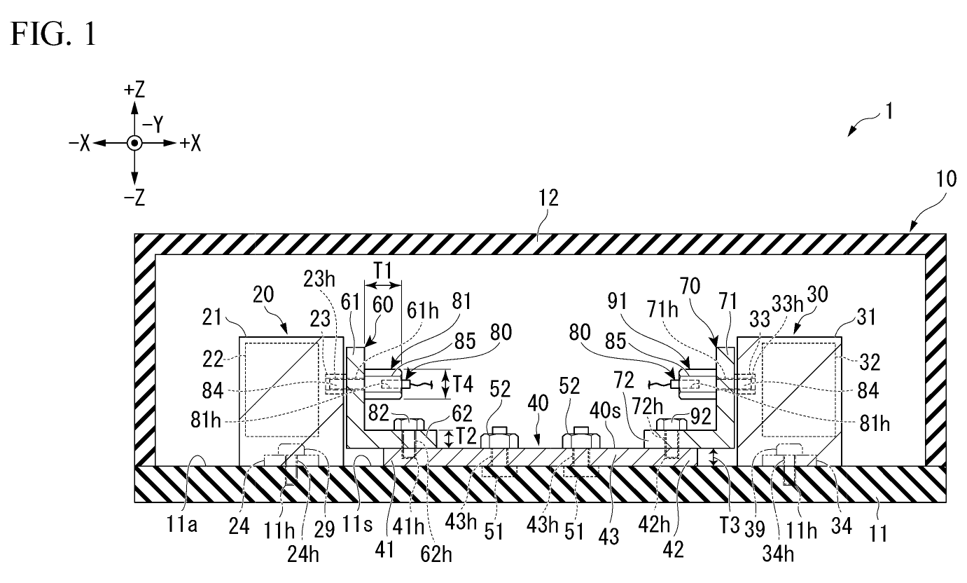

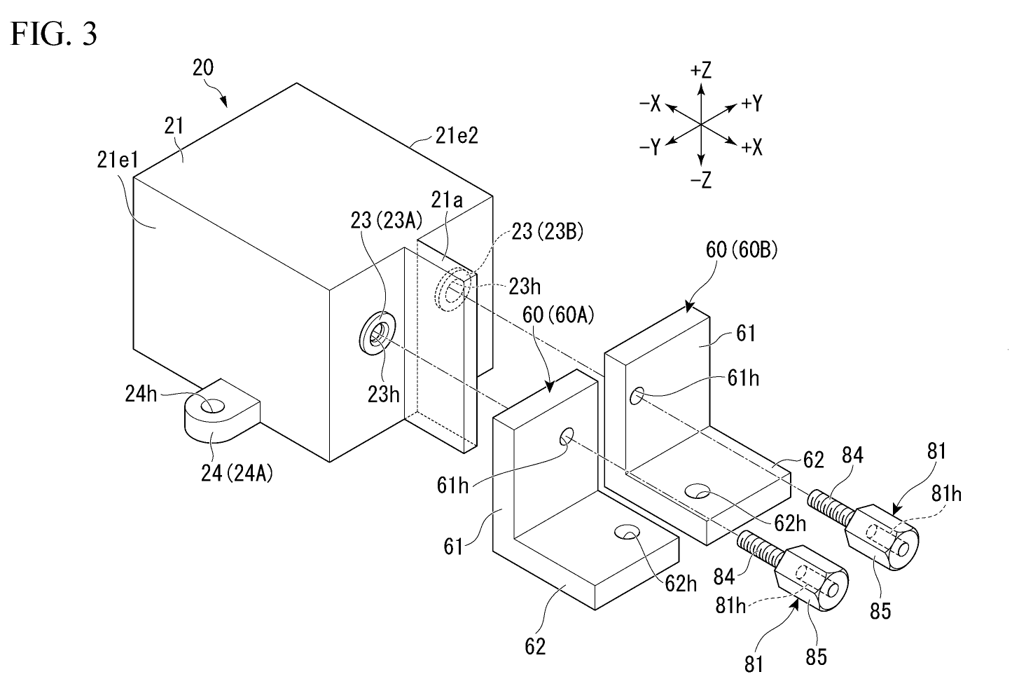

In the present disclosure, a +X direction, a -X direction, a +Y direction, a -Y direction, a +Z direction, and a -Z direction are defined as follows. The +X direction is a direction from a first electronic component 20 toward a first metal component 60 to be described later (see FIG. 1). The -X direction is a direction opposite to the +X direction. Hereinafter, the +X direction and the -X direction are simply referred to as an “X direction” when they are not distinguished from each other. The +Y direction is a direction from a first terminal portion 23A toward a second terminal portion 23B of the first electronic component 20 (see FIG. 3). The -Y direction is a direction opposite to the +Y direction. Hereinafter, the +Y direction and the -Y direction are simply referred to as a “Y direction” when they are not distinguished from each other. The +Z direction is a direction from a base member 11 toward a bus bar 40 to be described later (see FIG. 1). The -Z direction is a direction opposite to the +Z direction. Hereinafter, the +Z direction and the -Z direction are simply referred to as a “Z direction” when they are not distinguished from each other.

### First Embodiment

First, a first embodiment will be described. In the first embodiment, the X direction is an example of a “first direction”, and the Y direction and the Z direction are examples of a “second direction”.

### A1. Constitution of Electrical Connection Unit

FIG. 1 is a cross-sectional view illustrating an electrical connection unit 1 according to the first embodiment. The electrical connection unit 1 is used for a vehicle such as an electric vehicle (EV), a hybrid electric vehicle (HEV), or a plug-in hybrid electric vehicle (PHEV). The electrical connection unit 1 is, for example, a component called an electrical connection box or a junction box.

FIG. 1 is a cross-sectional view illustrating the electrical connection unit 1. The electrical connection unit 1 includes, for example, a housing 10, a plurality of electronic components 20 and 30, a plurality of bus bars 40 (only one is illustrated in FIG. 1), a plurality of metal components 60 and 70, and a temperature detector 80. The bus bar 40 and the metal components 60 and 70 are an example of a “wiring member”. In the first embodiment, the electronic components 20 and 30 are an example of a “connection target component”.

### A1.1 Housing

The housing 10 is an outer member that forms the outer shape of the electrical connection unit 1. The housing 10 accommodates the plurality of electronic components 20 and 30, the plurality of bus bars 40, and the plurality of metal components 60 and 70. The housing 10 includes, for example, a base member 11 and a cover member 12.

The base member 11 is, for example, a member that forms a bottom portion of the housing 10. The base member 11 is made of, for example, a synthetic resin and has an insulating property. The base member 11 has a support surface 11a exposed to the inside of the housing 10. At least a part of the support surface 11a has, for example, a plane 11s extending in the X direction and the Y direction.

A plurality of fixing members 51 (for example, screws) are fixed to the base member 11 of the present embodiment. The fixing member 51 is fixed to the base member 11 by being insert-molded into the base member 11. A head portion of the fixing member 51 is embedded in the base member 11. A shaft portion of the fixing member 51 protrudes in the +Z direction from the plane 11s of the base member 11 and extends in the +Z direction. The shaft portion of the fixing member 51 has a spiral screw thread. The fixing member 51 may be fixed to the base member 11 by means different from insert molding.

The cover member 12 is, for example, a member that forms a lid portion of the housing 10. In the present embodiment, the housing 10 is formed by combining the base member 11 and the cover member 12. The cover member 12 is made of, for example, a synthetic resin and has an insulating property. The bus bar 40 may be fixed to the cover member 12 instead of the base member 11.

### A1.2 Electronic Component

The plurality of electronic components 20 and 30 are electronic components mounted according to functions or applications required for the electrical connection unit 1. Each of the electronic components 20 and 30 is, for example, a connector, a fuse, a relay (for example, a mechanical relay or a semiconductor relay), a capacitor, a branch component, an electronic control unit, or an electronic component unit in which two or more of these are unitized. Note that the types of the electronic components 20 and 30 are not limited to the above examples. The electronic component 20 and the electronic component 30 may be the same type of components or different types of components. The electronic components 20 and 30 are, for example, heat generating components that generate heat at the time of energization.

Hereinafter, for convenience of description, the electronic component 20 may be referred to as a “first electronic component 20”. Further, the electronic component 30 may be referred to as a “second electronic component 30”. Note that the electrical connection unit 1 may include only one electronic component (for example, only one of the electronic components 20 and 30) instead of including the plurality of electronic components 20 and 30.

### A1.2.1 First Electronic Component

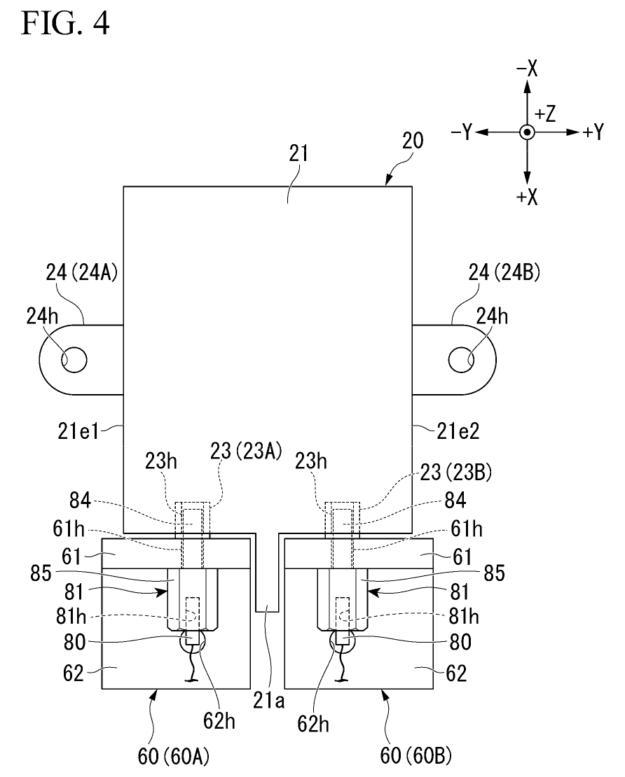

The first electronic component 20 includes, for example, a case 21, a body portion 22, a plurality of terminal portions 23 (see FIG. 3), and a plurality of attachment portions 24 (see FIG. 4).

### Case

The case 21 is an outer member that forms most of the outer shape of the first electronic component 20. The case 21 is made of, for example, a synthetic resin and has an insulating property. The case 21 accommodates the body portion 22. The case 21 and the body portion 22 may be integrally formed.

### Body Portion

The body portion 22 is a portion that performs a main function of the first electronic component 20. For example, in a case where the first electronic component 20 is a relay, the body portion 22 includes a switch (for example, a contact) that switches between a conductive state and a non-conductive state. For example, in a case where the first electronic component 20 is a fuse, the body portion 22 includes a fusion portion that melts when an overcurrent flows. For example, in a case where the first electronic component 20 is a capacitor, the body portion 22 includes a portion that stores electric charge.

### Terminal Portion

The terminal portion 23 is an electrical connection portion exposed to the outside of the case 21. The terminal portion 23 is electrically connected to the body portion 22 inside the case 21. In the present embodiment, the first electronic component 20 includes a first terminal portion 23A and a second terminal portion 23B as the plurality of terminal portions 23 (see FIG. 3). The first terminal portion 23A and the second terminal portion 23B are disposed at positions away from the support surface 11a of the base member 11 in the +Z direction.

In the present embodiment, the first terminal portion 23A and the second terminal portion 23B are provided at end portions on the +X direction side of the first electronic component 20. The first terminal portion 23A and the second terminal portion 23B are arranged side by side in the Y direction (see FIG. 3). Hereinafter, when the first terminal portion 23A and the second terminal portion 23B are not distinguished, they are simply referred to as “terminal portions 23”. The terminal portion 23 has an attachment hole 23h to which a fastening member 81 (for example, a screw) described later is attached. The attachment hole 23h is opened in the X direction. For example, the attachment hole 23h has a screw groove on an inner peripheral surface. The terminal portion 23 may be referred to as a “fastening portion”.

### Attachment Portion

The attachment portion 24 is a portion for fixing the first electronic component 20. For example, the attachment portion 24 is a portion for fixing the first electronic component 20 to the base member 11. In the present embodiment, the first electronic component 20 includes, as the plurality of attachment portions 24, a first attachment portion 24A and a second attachment portion 24B (see FIG. 4). The first attachment portion 24A and the second attachment portion 24B are separately disposed on both sides of the case 21 in the Y direction. For example, the first attachment portion 24A protrudes from the case 21 in the -Y direction. The second attachment portion 24B protrudes from the case 21 in the +Y direction.

Hereinafter, when the first attachment portion 24A and the second attachment portion 24B are not distinguished from each other, they are simply referred to as “attachment portions 24”. The attachment portion 24 has an attachment hole 24h to which the fastening member 29 (for example, a screw) is attached. The attachment hole 24h is opened in the Z direction. The attachment hole 24h is an insertion hole through which the fastening member 29 passes. In the present embodiment, the base member 11 has an attachment hole 11h at a position corresponding to the attachment hole 24h. The attachment hole 11h is opened in the Z direction. For example, the attachment hole 11h has a screw groove on the inner peripheral surface. In the present embodiment, the fastening member 29 passed through the attachment hole 24h of the attachment portion 24 is engaged with the attachment hole 11h, whereby the first electronic component 20 is fixed to the base member 11. The attachment hole 11h may be an attachment hole directly provided in the base member 11, or may be an attachment hole of an engagement member (for example, a nut) embedded in the base member 11 by, for example, insert molding or other means.

### A1.2.2 Second Electronic Component

The second electronic component 30 includes, for example, a case 31, a body portion 32, a plurality of terminal portions 33, and a plurality of attachment portions 34. Details of the second electronic component 30 are, for example, similar to those of the first electronic component 20. In the description regarding the second electronic component 30, “first electronic component 20”, “case 21”, “body portion 22”, “terminal portion 23”, “attachment hole 23h”, “attachment portion 24”, “attachment hole 24h”, “fastening member 29”, and “+X direction” in the description regarding the first electronic component 20 described above may be replaced with “second electronic component 30”, “case 31”, “body portion 32”, “terminal portion 33”, “attachment hole 33h”, “attachment portion 34”, “attachment hole 34h”, “fastening member 39”, and “-X direction”, respectively.

### A1.3 Bus Bar

The bus bar 40 is a wiring member included in the electrical connection unit 1. The bus bar 40 is, for example, a wiring member for electrically connecting the plurality of electronic components. Alternatively, the bus bar 40 may be a wiring member that connects one electronic component and the outside of the electrical connection unit 1.

The bus bar 40 is at least partially plate-shaped. In the present embodiment, the bus bar 40 has a plate shape over the entire bus bar 40. The bus bar 40 is disposed along the base member 11. The bus bar 40 has a planar plate surface 40s. The plate surface 40s of the bus bar 40 is parallel to the plane 11s of the base member 11 over the entire length of the bus bar 40. The bus bar 40 is fixed to the base member 11, for example. The bus bar 40 has a plate thickness T3. The plate thickness T3 is a thickness of the bus bar 40 in the Z direction.

Here, an example of the bus bar 40 will be described in detail by taking up the bus bar 40 that electrically connects the first electronic component 20 and the second electronic component 30. The bus bar 40 includes, for example, a first connection portion 41, a second connection portion 42, and an extension portion 43. In the present embodiment, each of the first connection portion 41, the second connection portion 42, and the extension portion 43 has a plate shape along the X direction and the Y direction.

### First Connection Portion

The first connection portion 41 is a portion electrically connected to the first electronic component 20. The first connection portion 41 is provided at one end portion of the bus bar 40. The first connection portion 41 has an attachment hole 41h through which the second fastening member 82 (for example, a screw) passes. The attachment hole 41h is opened in the Z direction. In the present embodiment, the first connection portion 41 is disposed away from the terminal portion 23 of the first electronic component 20. For example, the first connection portion 41 is disposed along the base member 11.

### Second Connection Portion

The second connection portion 42 is a portion electrically connected to the second electronic component 30. The second connection portion 42 is provided at the other end portion of the bus bar 40. The second connection portion 42 has an attachment hole 42h through which the fastening member 92 (for example, a screw) passes. The attachment hole 42h is opened in the Z direction. In the present embodiment, the second connection portion 42 is disposed away from the terminal portion 33 of the second electronic component 30. For example, the second connection portion 42 is disposed along the base member 11.

### Extension Portion

The extension portion 43 is provided between the first connection portion 41 and the second connection portion 42. The extension portion 43 extends, for example, in the X direction along the base member 11, and connects the first connection portion 41 and the second connection portion 42. In the present embodiment, the extension portion 43 has an attachment hole 43h through which the fixing member 51 passes. The bus bar 40 is placed on the plane 11s of the base member 11 in a state where the shaft portion of the fixing member 51 passes through the attachment hole 43h. The engagement member 52 (for example, a nut) is attached to the shaft portion of the fixing member 51 from the +Z direction side in a state where the shaft portion of the fixing member 51 passes through the attachment hole 43h, whereby the bus bar 40 is fixed to the base member 11.

### A1.4 Metal Component

The metal component 60 is disposed between the first connection portion 41 and the terminal portion 23. The metal component 60 is in contact with the terminal portion 23. The metal component 60 is electrically connected to both the terminal portion 23 and the bus bar 40. Similarly, the metal component 70 is disposed between the second connection portion 42 and the terminal portion 33. The metal component 70 is in contact with the terminal portion 33. The metal component 70 is electrically connected to both the terminal portion 33 and the bus bar 40.

Hereinafter, for convenience of description, the metal component 60 may be referred to as a “first metal component 60”. In addition, the metal component 70 may be referred to as a “second metal component 70”. Note that the electrical connection unit 1 may include only one metal component (for example, only one of the metal components 60 and 70) instead of including the plurality of metal components 60 and 70.

### A1.4.1 First Metal Component

The first metal component 60 is disposed between the first electronic component 20 and the bus bar 40. In the present disclosure, the phrase “the metal component is disposed between the electronic component and the bus bar” is not limited to a case where a part of the metal component is located between the electronic component and the bus bar when viewed from the X direction or the Y direction. The phrase “the metal component is disposed between the electronic component and the bus bar” may correspond to a case where a part of the metal component is located between the electronic component and the bus bar when viewed from a direction inclined with respect to the X direction or the Y direction.

The first metal component 60 electrically connects the terminal portion 23 of the first electronic component 20 and the first connection portion 41 of the bus bar 40. The first metal component 60 includes, for example, a first portion 61 and a second portion 62.

### First Portion

The first portion 61 is a portion connected to the terminal portion 23 of the first electronic component 20. The first portion 61 is a plate-shaped or rectangular parallelepiped portion extending in the Z direction. The first portion 61 extends in the Z direction along one end portion (for example, an end portion in the Y direction) of the electronic component 20. The first portion 61 is in a posture standing in the Z direction with respect to the support surface 11a (for example, the plane 11s) of the base member 11. The first portion 61 is adjacent to the electronic component 20 in the horizontal direction (for example, the X direction). For example, the first portion 61 is adjacent to the terminal portion 23 of the electronic component 20 in the horizontal direction (for example, the X direction), and is connected to the terminal portion 23 of the electronic component 20 from the horizontal direction (for example, the X direction).

The first portion 61 has the first attachment hole 61h through which a fastening member 81 (for example, a screw or a bolt) passes. The first attachment hole 61h is opened in the horizontal direction (for example, the X direction). The first portion 61 is physically and electrically connected to the terminal portion 23 of the electronic component 20 by engagement of the fastening member 81 passed through the first attachment hole 61h with the attachment hole 23h of the terminal portion 23 of the electronic component 20.

### Second Portion

The second portion 62 is a portion connected to the first connection portion 41 of the bus bar 40. The second portion 62 protrudes in the +X direction from an end portion of the first portion 61 on the -Z direction side. The second portion 62 is a plate portion extending in the horizontal direction (for example, the X direction and the Y direction). The second portion 62 extends in the X direction along the first connection portion 41 of the bus bar 40. In the present embodiment, the first portion 61 and the second portion 62 form one L-shaped piece of the first metal component 60.

The second portion 62 is adjacent to the first connection portion 41 of the bus bar 40 in the Z direction. The first portion 61 faces the first connection portion 41 of the bus bar 40 from the +Z direction side. The second portion 62 is connected to the first connection portion 41 of the bus bar 40 from the Z direction.

In the present embodiment, the second portion 62 has a second attachment hole 62h through which the second fastening member 82 (for example, a screw) passes. The second attachment hole 62h is opened in the Z direction. The second portion 62 is physically and electrically connected to the first connection portion 41 of the bus bar 40 by engagement of the second fastening member 82 passed through the second attachment hole 62h with the attachment hole 41h of the first connection portion 41 of the bus bar 40. The thickness of the first portion 61 in the X direction and the thickness of the second portion 62 in the Z direction in the present embodiment are the same thickness T2. The thickness T2 of the present embodiment is the same as the thickness T3 of the bus bar 40. For example, the thickness of the first portion 61 in the X direction may be different from the thickness of the second portion 62 in the Z direction. The thickness T2 and the thickness T3 may be different.

### Arrangement Example of First Metal Component

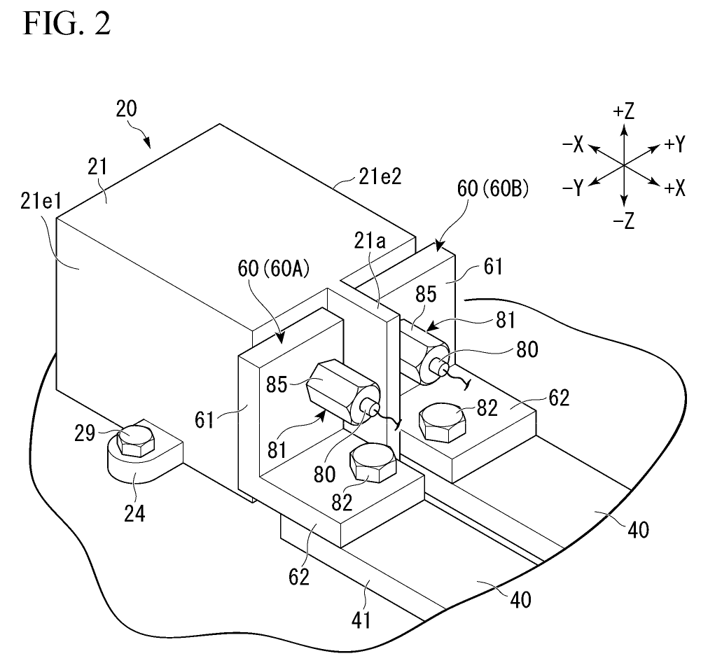

FIG. 2 is a perspective view illustrating a part of the electrical connection unit 1. FIG. 3 is an exploded perspective view of a part of the electrical connection unit 1. In the present embodiment, the electrical connection unit 1 includes a metal component 60A and a metal component 60B as the plurality of first metal components 60. The metal component 60A and the metal component 60B have, for example, symmetrical shapes in the Y direction.

The metal component 60A is disposed corresponding to a half portion of the first electronic component 20 on the -Y direction side. The metal component 60A is adjacent to the terminal portion 23A of the first electronic component 20 in the X direction, and is connected to the terminal portion 23A of the first electronic component 20 in the X direction. On the other hand, the metal component 60B is disposed corresponding to a half portion of the first electronic component 20 on the +Y direction side. The metal component 60B is adjacent to the terminal portion 23B of the first electronic component 20 in the X direction, and is connected to the terminal portion 23B of the first electronic component 20 in the X direction.

In the present embodiment, the case 21 has an insulating wall 21a protruding in the +X direction (see FIG. 2). The insulating wall 21a is provided at the center of the case 21 in the Y direction. The insulating wall 21a extends in the X direction and the Z direction. For example, the insulating wall 21a extends over the entire height of the case 21 in the Z direction. The insulating wall 21a is disposed between the first terminal portion 23A and the second terminal portion 23B. The insulating wall 21a electrically insulates the first terminal portion 23A from the second terminal portion 23B. In the present embodiment, the insulating wall 21a is disposed between the first portion 61 of the metal component 60A and the first portion 61 of the metal component 60B. The insulating wall 21a electrically insulates the first portion 61 of the metal component 60A from the first portion 61 of the metal component 60B.

FIG. 4 is a plan view illustrating the first electronic component 20 and the metal components 60A and 60B. In the present embodiment, the case 21 of the first electronic component 20 has an end 21e1 in the -Y direction and an end 21e2 in the +Y direction.

A part of the metal component 60A protrudes toward the -Y direction side from the end 21e1 of the case 21 of the first electronic component 20. A part of the metal component 60A protrudes to a region not overlapping the first electronic component 20 when viewed in the X direction. Similarly, a part of the metal component 60B protrudes toward the +Y direction side from the end 21e2 of the case 21 of the first electronic component 20. A part of the metal component 60B protrudes to a region not overlapping the first electronic component 20 when viewed in the X direction.

### A1.4.2 Second Metal Component

Next, referring back to FIG. 1, the second metal component 70 will be described. The second metal component 70 is disposed between the second electronic component 30 and the bus bar 40. The second metal component 70 electrically connects the terminal portion 33 of the second electronic component 30 and the second connection portion 42 of the bus bar 40. The second metal component 70 includes, for example, a first portion 71 and a second portion 72.

Details of the second metal component 70 are, for example, similar to those of the first metal component 60. In the description regarding the second metal component 70, “first portion 61”, “first attachment hole 61h”, “second portion 62”, “second attachment hole 62h”, “first electronic component 20”, “body portion 22”, “terminal portion 23”, “attachment hole 23h”, “fastening member 81”, “fastening member 82”, “first connection portion 41”, “attachment hole 41h”, and “+X direction” in the description regarding the first metal component 60 described above may be replaced with “first portion 71”, “first attachment hole 71h”, “second portion 72”, “second attachment hole 72h”, “second electronic component 30”, “body portion 32”, “terminal portion 33”, “attachment hole 33h”, “fastening member 91”, “fastening member 92”, “second connection portion 42”, “attachment hole 42h”, and “-X direction”, respectively.

### A1.4.3 Fastening Member

The fastening members 81 and 82 fix the first metal component 60 to the electronic component 20 and the bus bar 40. The fastening members 91 and 92 fix the second metal component 70 to the electronic component 30 and the bus bar 40. Hereinafter, for convenience of description, the fastening member 81 may be referred to as a “first fastening member 81”. In addition, the fastening member 82 may be referred to as a “second fastening member 82”. Similarly, the fastening member 91 may be referred to as a “first fastening member 91”. In addition, the fastening member 92 may be referred to as a “second fastening member 92”. In the present embodiment, the attachment holes 23h and 33h are examples of “fastening hole portions”.

### First Fastening Member

The first fastening member 81 fixes the first portion 61 of the metal component 60 to the terminal portion 23 of the electronic component 20. The first fastening member 81 is a metal bolt having a shaft portion 84 and a head portion 85. The material of the first fastening member 81 is, but is not limited to, copper, a copper alloy, aluminum, an aluminum alloy, steel, stainless steel, magnesium, a magnesium alloy, titanium, a titanium alloy, or the like.

The shaft portion 84 has a columnar shape extending in the X direction and has a screw thread formed on the outer peripheral surface. In the present embodiment, the attachment hole 23h of the terminal portion 23 has a spiral screw groove on the inner peripheral surface. The shaft portion 84 can be screwed into the attachment hole 23h of the terminal portion 23. The head portion 85 has a diameter larger than that of the shaft portion 84. In the present embodiment, the length T1 of the head portion 85 in the X direction is larger than the thickness T2 of the metal component 60 and the thickness T3 of the bus bar 40. The length T4 (diameter) of the head portion 85 in a direction perpendicular to the X direction (Y direction and Z direction) is also larger than the thickness T2 of the metal component 60 and the thickness T3 of the bus bar 40. Since the lengths T1 and T4 are larger than the thicknesses T2 and T3, the head portion 85 of the present embodiment has a heat storage function. In the present embodiment, the outer periphery of the head portion 85 has a hexagonal shape for using a tool such as a spanner. However, the shape of the head portion 85 is not limited to a hexagon, and an appropriate shape can be adopted according to a fastening tool.

In the present embodiment, the attachment hole 23h is, for example, a through hole penetrating the terminal portion 23 in the X direction. The inner peripheral surface of the attachment hole 23h has a screw groove. However, as described above, the “attachment hole” in the present disclosure is not limited to a hole having a screw groove, and may be a hole having no screw groove. In the present disclosure, the “attachment hole” is not limited to the through hole, and may be a bottomed hole. For example, the attachment hole 23h may be a hole that does not have a screw groove and is engaged with the shaft portion 84 of the first fastening member 81.

For example, the shaft portion 84 is inserted into the attachment hole 23h of the electronic component 20 and the attachment hole 61h of the metal component 60 in a state where the attachment hole 23h of the electronic component 20 and the attachment hole 61h of the metal component 60 overlap each other in the X direction. The shaft portion 84 is screwed into the attachment hole 23h in a state of being passed through the attachment hole 61h of the metal component 60. The shaft portion 84 is screwed into the attachment hole 61h, so that the first portion 61 of the metal component 60 is fixed to the terminal portion 23 by the first fastening member 81.

The head portion 85 has a hole portion 81h that accommodates a temperature detector 80 to be described later. In the present embodiment, in a state where the shaft portion 84 is inserted into the attachment hole 23h, the hole portion 81h has an opening on a surface of the head portion 85 facing the +X direction. The hole portion 81h is recessed in the -X direction from the surface of the head portion 85 facing the +X direction. In the present embodiment, the hole portion 81h forms a columnar space extending in the X direction. The hole portion 81h inserts and accommodates the columnar temperature detector 80 from the +X direction.

Details of the first fastening member 91 are, for example, similar to those of the first fastening member 81. In the description regarding the first fastening member 91, “shaft portion 84”, “head portion 85”, “metal component 60”, “attachment hole 61h”, “first electronic component 20”, “terminal portion 23”, “attachment hole 23h”, “+X direction”, and “-X direction” in the description regarding the first fastening member 81 described above may be replaced with “shaft portion 94”, “head portion 95”, “metal component 70”, “attachment hole 71h”, “second electronic component 30”, “terminal portion 33”, “attachment hole 33h”, “-X direction”, and “+X direction”, respectively.

### Temperature Detector

The temperature detector 80 is accommodated in the hole portions 81h and 91h provided in the first fastening members 81 and 91, respectively. In the present embodiment, the temperature detector 80 is accommodated in the hole portions 81h and 91h, and is fixed to the first fastening members 81 and 91 by, for example, a thermally conductive adhesive. The temperature detector 80 can detect temperatures of the first fastening members 81 and 91. The temperature detector 80 outputs a temperature detection result as an electric signal. The detection result of the temperature detector 80 can be input to a control device that performs temperature monitoring, or can be displayed on an external display. As the temperature detector 80, for example, a thermistor can be used. In the present embodiment, the temperature detector 80 has an elongated columnar shape such as a column or a prism, and an electric wire for output is connected to an end portion in the longitudinal direction (end portion in the X direction) thereof.

The temperature detector 80 detects temperatures of the first fastening members 81 and 91. On the other hand, the shaft portions 84 of the first fastening members 81 and 91 are in direct contact with the terminal portions 23 and 33. The head portions 85 of the first fastening members 81 and 91 are in contact with the metal components 60 and 70. The metal components 60 and 70 are in direct contact with the terminal portions 23 and 33. That is, the head portion 85 is indirectly connected to the terminal portions 23 and 33. Therefore, heat can be transferred between the terminal portions 23 and 33 and the metal components 60 and 70, and between the metal components 60 and 70 and the head portion 85. The temperature detector 80 indirectly detects the temperatures of the terminal portions 23 and 33 by detecting the temperatures of the first fastening members 81 and 91.

### Second Fastening Member

The second fastening member 82 fixes the second portions 62 and 72 of the metal components 60 and 70 to the bus bar 40. In the present embodiment, the second fastening member 82 is a bolt, and engages with the attachment holes 41h and 42h of the bus bar 40 through the second attachment holes 62h and 72h of the second portions 62 and 72 from the +Z direction. By this engagement, the second portions 62 and 72 of the metal components 60 and 70 and the bus bar 40 are physically and electrically connected.

### A2. Method of Manufacturing Electrical Connection Unit

Next, a method of manufacturing the electrical connection unit 1 will be described.

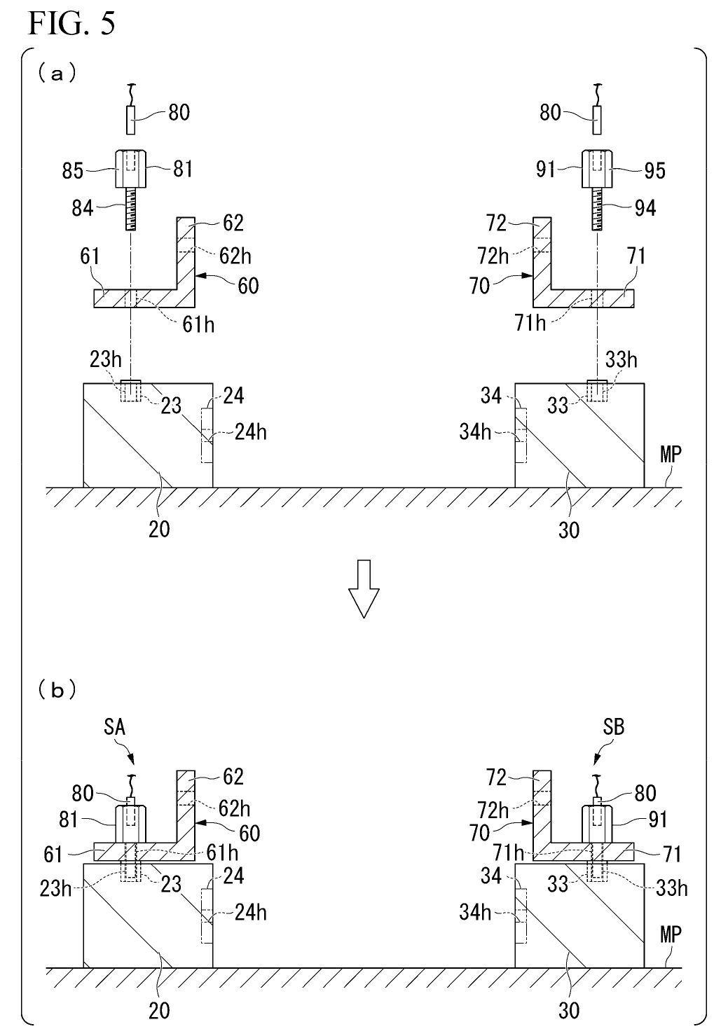

FIGS. 5 to 7 are cross-sectional views for describing the method of manufacturing the electrical connection unit 1.

### First Step

FIG. 5 illustrates a first step and a second step. In the first step, the temperature detector 80 is inserted into the hole portions 81h of the first fastening members 81 and 91, and the temperature detector 80 is fixed in the hole portions 81h using a thermally conductive adhesive or the like. By this fixing, the first fastening members 81 and 91 and the temperature detector 80 are integrated. In the present embodiment, the temperature detector 80 is integrated with each of the plurality of first fastening members 81 and 91.

### Second Step

In the second step, the first metal component 60 is fixed to the terminal portion 23 of the first electronic component 20 using the first fastening member 81. By this fixing, a first assembly SA in which the first electronic component 20 and the first metal component 60 are integrated is formed.

The second step is performed, for example, as follows. First, the first electronic component 20 is placed on a placement table MP in a posture in which the attachment hole 23h of the terminal portion 23 of the first electronic component 20 is directed in the vertical direction. Next, the first metal component 60 is placed on the first electronic component 20 in a posture in which the first attachment hole 61h of the first metal component 60 is directed in the vertical direction. The first attachment hole 61h of the first metal component 60 and the attachment hole 23h of the terminal portion 23 of the first electronic component 20 are aligned. The first step is performed in a state where the first electronic component 20 and the first metal component 60 are in the first posture. The first posture is a posture in which the attachment hole 23h and the first attachment hole 61h are directed in the vertical direction.

Next, the first fastening member 81 is inserted into the first attachment hole 61h of the first metal component 60 from the vertical direction. The first fastening member 81 having passed through the first attachment hole 61h of the first metal component 60 is engaged with the attachment hole 23h of the terminal portion 23 of the first electronic component 20. By this engagement, the first assembly SA in which the first electronic component 20 and the first metal component 60 are integrated is formed.

Similarly, the second metal component 70 is fixed to the terminal portion 33 of the second electronic component 30 using the first fastening member 91. By this fixing, a second assembly SB in which the second electronic component 30 and the second metal component 70 are integrated is formed.

### Third Step

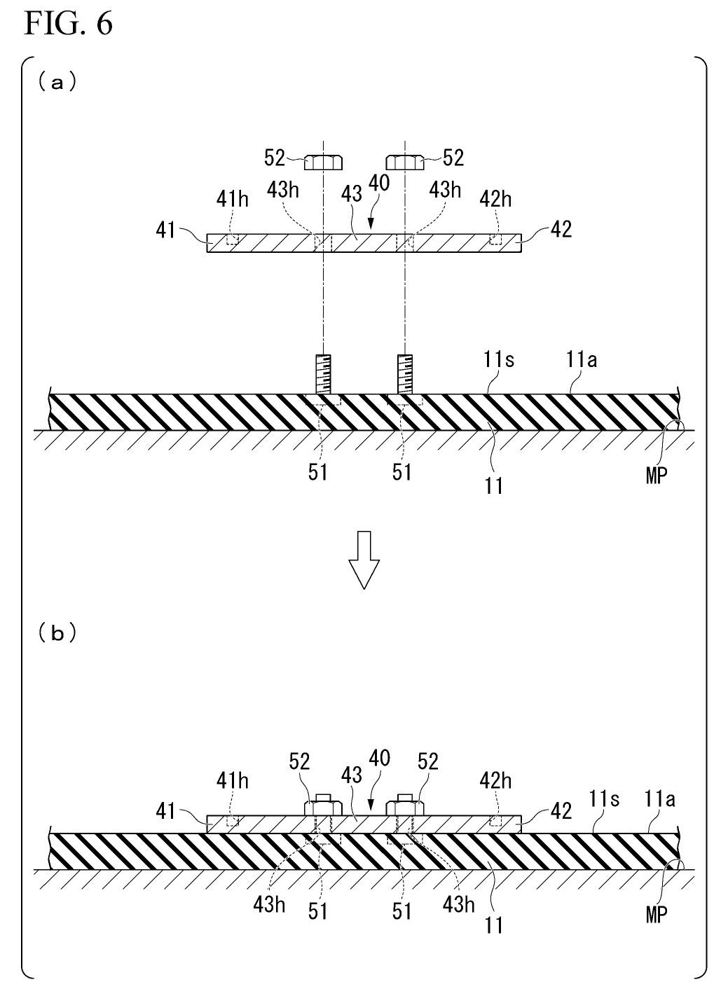

FIG. 6 illustrates a third step. In the third step, the bus bar 40 is fixed to the base member 11. This step may be performed before the second step, after the second step, or in parallel with the second step.

The third step is performed, for example, as follows. As described above, the fixing member 51 is previously fixed to the base member 11, for example. The fixing member 51 protrudes along the vertical direction. The bus bar 40 is placed on the base member 11 such that the fixing member 51 is inserted into the attachment hole 43h of the bus bar 40 along the vertical direction. Next, the engagement member 52 (for example, a nut) is engaged with the upper end portion of the fixing member 51 from the vertical direction. By this engagement, the bus bar 40 is fixed to the base member 11. In the present embodiment, the bus bar 40 is fixed to the base member 11 before fixing the electronic components 20 and 30 to the base member 11.

### Fourth Step

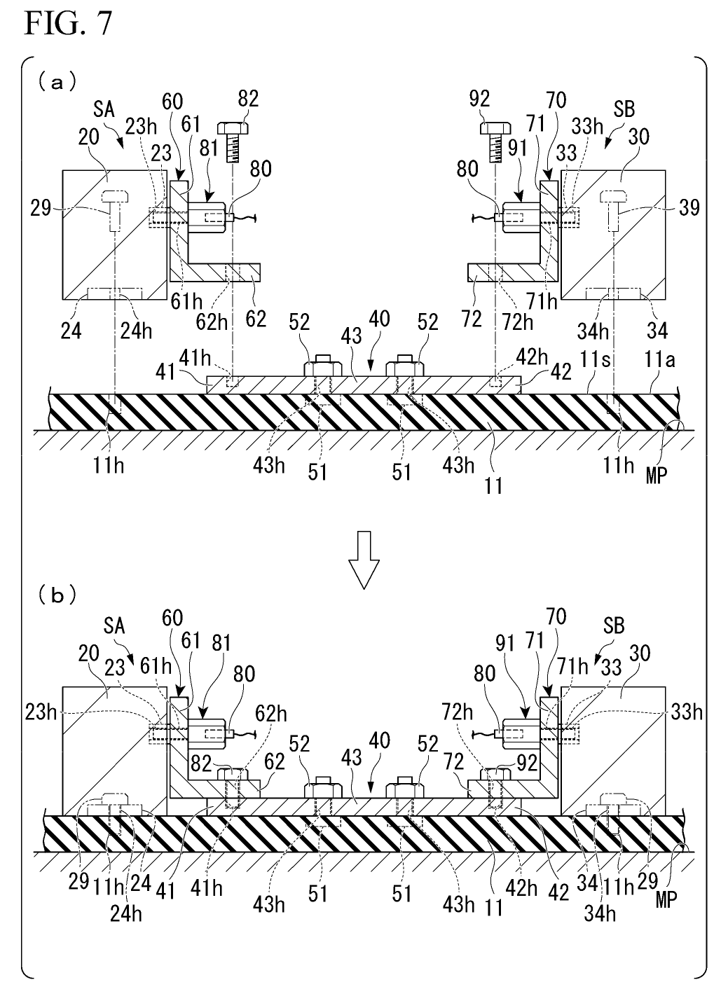

FIG. 7 illustrates a fourth step. The fourth step is performed after the second step and the third step. In the fourth step, the first assembly SA is fixed to the first connection portion 41 of the bus bar 40 using the second fastening member 82. For example, the first metal component 60 included in the first assembly SA is fixed to the first connection portion 41 of the bus bar 40 using the second fastening member 82. By this fixing, the first electronic component 20 and the bus bar 40 are electrically connected.

The fourth step is performed, for example, as follows. First, the posture of the first assembly SA is rotated by 90 degrees from the first step. That is, the first posture (see FIG. 5) in which the attachment hole 23h and the first attachment hole 61h are directed in the vertical direction is changed to the second posture (see FIG. 7) in which the attachment hole 23h and the first attachment hole 61h are directed in the horizontal direction and the second attachment hole 62h of the first metal component 60 is directed in the vertical direction.

In the second posture, the second portion 62 of the first metal component 60 is placed on the first connection portion 41 of the bus bar 40. The second attachment hole 62h of the first metal component 60 and the attachment hole 41h of the first connection portion 41 of the bus bar 40 are aligned.

Next, the second fastening member 82 is inserted into the second attachment hole 62h of the first metal component 60 from the vertical direction. The second fastening member 82 having passed through the second attachment hole 62h of the first metal component 60 is engaged with the attachment hole 41h of the first connection portion 41 of the bus bar 40. By this engagement, the first metal component 60 is fixed to the first connection portion 41 of the bus bar 40. That is, the first assembly SA is fixed to the first connection portion 41 of the bus bar 40. By this fixing, the first electronic component 20 and the first connection portion 41 of the bus bar 40 are electrically connected. In the present embodiment, the direction in which the bus bar 40 is fixed to the base member 11 coincides with the direction in which the first assembly SA is fixed to the bus bar 40.

In the fourth step, the attachment portion 24 of the first electronic component 20 may be fixed to the base member 11 using the fastening member 29. This work is performed as follows, for example. First, the attachment hole 24h of the attachment portion 24 of the first electronic component 20 and the attachment hole 11h of the base member 11 are aligned. Next, the fastening member 29 is inserted into the attachment hole 24h of the first electronic component 20 from the vertical direction. The fastening member 29 passed through the attachment hole 24h of the first electronic component 20 is engaged with the attachment hole 11h of the base member 11. By this engagement, the first electronic component 20 is fixed to the base member 11. The work of fixing the first electronic component 20 to the base member 11 using the fastening member 29 may be performed before or after the work of fixing the first metal component 60 to the bus bar 40 using the second fastening member 82. In the present embodiment, a direction in which the bus bar 40 is fixed to the base member 11, a direction in which the first assembly SA is fixed to the bus bar 40, and a direction in which the first electronic component 20 is fixed to the base member 11 coincide with each other.

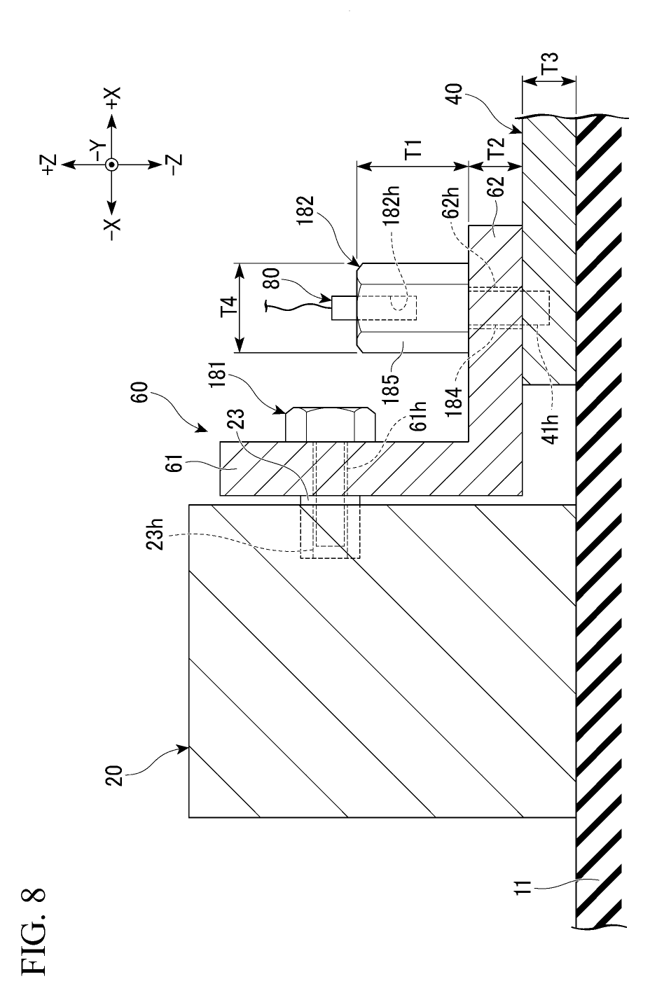

Similarly, the posture of the second assembly SB is rotated by 90 degrees from the first step. That is, the first posture (see FIG. 6) in which the attachment hole 33h and the first attachment hole 71h are directed in the vertical direction is changed to the second posture (see FIG. 8) in which the attachment hole 33h and the first attachment hole 71h are directed in the horizontal direction and the second attachment hole 72h of the second metal component 70 is directed in the vertical direction.

In the second posture, the second portion 72 of the second metal component 70 is placed on the second connection portion 42 of the bus bar 40. The second attachment hole 72h of the second metal component 70 and the attachment hole 42h of the second connection portion 42 of the bus bar 40 are aligned.

Next, the second fastening member 92 is inserted into the second attachment hole 72h of the second metal component 70 from the vertical direction. The second fastening member 92 passed through the second attachment hole 72h of the second metal component 70 is engaged with the attachment hole 42h of the second connection portion 42 of the bus bar 40. By this engagement, the second metal component 70 is fixed to the second connection portion 42 of the bus bar 40. That is, the second assembly SB is fixed to the second connection portion 42 of the bus bar 40. By this fixing, the second electronic component 30 and the second connection portion 42 of the bus bar 40 are electrically connected. In the present embodiment, the direction in which the bus bar 40 is fixed to the base member 11 coincides with the direction in which the second assembly SB is fixed to the bus bar 40.

In the fourth step, the attachment portion 34 of the second electronic component 30 may be fixed to the base member 11 using the fastening member 39. This work is performed as follows, for example. First, the attachment hole 34h of the attachment portion 34 of the second electronic component 30 and the attachment hole 11h of the base member 11 are aligned. Next, the fastening member 39 is inserted into the attachment hole 34h of the second electronic component 30 from the vertical direction. The fastening member 39 passed through the attachment hole 34h of the second electronic component 30 is engaged with the attachment hole 11h of the base member 11. By this engagement, the second electronic component 30 is fixed to the base member 11. The work of fixing the second electronic component 30 to the base member 11 using the fastening member 39 may be performed before or after the work of fixing the second metal component 70 to the bus bar 40 using the second fastening member 92. In the present embodiment, a direction in which the bus bar 40 is fixed to the base member 11, a direction in which the second assembly SB is fixed to the bus bar 40, and a direction in which the second electronic component 30 is fixed to the base member 11 coincide with each other.

### A3. Operation of Invention

Next, an operation of the electrical connection unit 1 in the invention will be described.

When the first electronic component 20 is energized, the body portion 22 of the first electronic component 20 generates heat, and the terminal portion 23 connected to the body portion 22 becomes hot. A part of the heat of the terminal portion 23 is transferred to the metal component 60. The terminal portion 23 and the metal component 60 are fixed by the first fastening member 81. The temperature detector 80 is attached to the first fastening member 81. Therefore, the temperature of the terminal portion 23 can be indirectly detected by the temperature detector 80. The operation of the invention similarly applies to a constitution in which the metal component 70 is fixed to the terminal portion 33 of the second electronic component 30 using the first fastening member 91.

### A4. Advantages

In the present embodiment, the electrical connection unit 1 includes the electronic components 20 and 30 having the terminal portions 23 and 33, and the metal components 60 and 70 electrically connected to the terminal portions 23 and 33. The electrical connection unit 1 further includes the terminal portions 23 and 33 to which the metal components 60 and 70 are connected, and the fastening members 81 and 91 that are in contact with the metal components 60 and 70 and fix the metal components 60 and 70 to the terminal portions 23 and 33. The electrical connection unit 1 further includes the temperature detector 80 that is attached to the fastening members 81 and 91 and is capable of detecting a temperature.

According to such a constitution, it is possible to easily detect the temperatures of the terminal portions 23 and 33 only by fixing the metal components 60 and 70 to the terminal portions 23 and 33 using the first fastening members 81 and 91 to which the temperature detector 80 is attached. For example, it is possible to suppress complication of the work of installing the temperature detector 80 as compared with the case of installing the temperature detector in the first fastening member 81. Therefore, the burden on the operator can be reduced.

In the present embodiment, the fastening members 81 and 91 include the shaft portion 84 having a screw thread formed on the outer peripheral surface and the head portion 85 having a larger diameter than the shaft portion 84. The head portion 85 has the hole portions 81h and 91h capable of accommodating the temperature detector 80. The terminal portions 23 and 33 include the attachment holes 23h and 33h in which a screw groove is formed on the inner peripheral surface and the shaft portion 84 can be screwed.

According to such a constitution, the fastening members 81 and 91 can be fixed to the terminal portions 23 and 33 only by screwing the shaft portion 84 into the attachment holes 23h and 33h. Since the hole portions 81h and 91h may be formed in the head portion 85 having a larger diameter than the shaft portion 84, the hole portions 81h and 91h can be easily provided. Since the temperature detector 80 only needs to be inserted into and fixed to the hole portions 81h and 91h formed in the head portion 85, the temperature detector 80 can be easily attached to the fastening members 81 and 91.

In the present embodiment, the length T4 of the head portion 85 in the X direction in which the shaft portion 84 extends and the length T1 of the head portion 85 in the direction perpendicular to the X direction are larger than the thicknesses T2 and T3 of the metal components 60 and 70 and the bus bar 40.

According to such a constitution, a heat capacity larger than those of the metal components 60 and 70 and the bus bar 40 at the position fixed by the fastening members 81 and 91 is secured in the head portion 85. Therefore, the head portion 85 can have a large heat storage function. A part of heat transferred to the metal components 60 and 70 can be stored (absorbed) at least temporarily by the head portions 85 of the fastening members 81 and 91. According to this structure, it is possible to suppress occurrence of a large temperature rise in a part of the electrical connection unit 1 and/or an increase in thermal interference with the electronic components 20 and 30. Thermal characteristics (for example, heat dissipation or heat storage properties) of the electrical connection unit 1 can be improved.

### Modification of First Embodiment

In the first embodiment, the case where the temperature detector 80 is attached to the first fastening members 81 and 91 before the metal components 60 and 70 are fixed to the electronic components 20 and 30 by the first fastening members 81 and 91 has been described. However, the temperature detector 80 may be attached to the first fastening members 81 and 91 after the metal components 60 and 70 are attached to the electronic components 20 and 30 by the first fastening members 81 and 91.

### Second Embodiment

Next, a second embodiment will be described. The second embodiment is different from the first embodiment in that a fastening member to which a temperature detector is attached fixes a metal component to a bus bar. Constitutions other than those to be described below are the same as the constitutions of the first embodiment. In the second embodiment, a Z direction is an example of a “first direction”, and an X direction and a Y direction are examples of a “second direction”.

### B1 Fastening Member

FIG. 8 is a cross-sectional view illustrating an electronic component, a metal component, a bus bar, and a fastening member according to the second embodiment.

Fastening members 181 and 182 fix a metal component 60 and a bus bar 40. In the present embodiment, the metal component 60 is an example of a “wiring member”, and the bus bar 40 is an example of a “connection target component”. An attachment hole 41h is an example of a “fastening hole portion”.

Hereinafter, for convenience of description, the fastening member 181 may be referred to as a “first fastening member 181”. In addition, the fastening member 182 may be referred to as a “second fastening member 182”. An attachment hole 23h is an example of a “fastening hole portion”. Since a fastening member for fixing the second metal component 70 and the bus bar 40 has the same constitution as those of the fastening members 181 and 182, the description thereof is omitted.

### First Fastening Member

The first fastening member 181 fixes the first portion 61 of the metal component 60 to the terminal portion 23 of the electronic component 20. In the present embodiment, the first fastening member 181 is a bolt. The first fastening member 181 and the second fastening member 82 of the first embodiment have the same shape. The first fastening member 181 is engaged with the attachment hole 23h of the terminal portion 23 through the first attachment hole 61h of the first portion 61 from the +Z direction. By this engagement, the first portion 61 of the metal component 60 and the terminal portion 23 are physically and electrically connected.

### Second Fastening Member

The second fastening member 182 fixes the second portion 62 of the metal component 60 to the bus bar 40. The second fastening member 182 is a metal bolt having a shaft portion 184 and a head portion 185. A material of the second fastening member 182 is, but is not limited to, copper, a copper alloy, aluminum, an aluminum alloy, steel, stainless steel, magnesium, a magnesium alloy, titanium, a titanium alloy, or the like. The constitution of the second fastening member 182 of the present embodiment is the same as that of the first fastening member 81 of the first embodiment.

The shaft portion 184 has a columnar shape extending in the Z direction, and has a screw thread formed on an outer peripheral surface. The shaft portion 184 can be screwed into the attachment hole 41h of the bus bar 40. The head portion 185 has a diameter larger than that of the shaft portion 184. In the present embodiment, the length T1 of the head portion 185 in the Z direction is larger than the thickness T2 of the metal component 60 and the thickness T3 of the bus bar 40. The length T4 of the head portion 185 in the direction perpendicular to the Z direction (X direction and Y direction) is also larger than the thickness T2 of the metal component 60 and the thickness T3 of the bus bar 40. The head portion 185 of the present embodiment also has a heat storage function similarly to the head portion 85 of the first embodiment. In the present embodiment, the outer periphery of the head portion 185 has a hexagonal shape because a tool such as a spanner is used. However, the shape of the head portion 185 is not limited to a hexagon, and an appropriate shape can be adopted according to a fastening tool.

In the present embodiment, the attachment hole 41h is, for example, a through hole penetrating the bus bar 40 in the Z direction. In the present embodiment, the attachment hole 41h has a spiral screw groove on the inner peripheral surface. For example, the attachment hole 41h may be a hole that does not have a screw groove and is engaged with the shaft portion 184 of the second fastening member 182.

For example, the shaft portion 184 is inserted into the attachment hole 41h of the bus bar 40 and the attachment hole 61h of the metal component 60 in a state where the attachment hole 41h of the bus bar 40 and the attachment hole 61h of the metal component 60 overlap each other in the Z direction. The shaft portion 184 is screwed into the attachment hole 41h in a state of being passed through the attachment hole 61h of the metal component 60. The shaft portion 184 is screwed into the attachment hole 61h, so that the second portion 62 of the metal component 60 is fixed to the bus bar 40 by the second fastening member 182. The constitution is not limited to the constitution in which the second fastening member 182 is engaged with the attachment hole 41h, and may include a case where fastening is performed by combining a component (for example, an engagement member such as a nut) different from the bus bar 40.

The head portion 185 has a hole portion 182h that accommodates the temperature detector 80. In the present embodiment, in a state where the shaft portion 184 is inserted into the attachment hole 41h, the hole portion 182h has an opening on a surface of the head portion 185 facing the +Z direction. The hole portion 182h is recessed in the -Z direction from the surface of the head portion 185 facing the +Z direction. In the present embodiment, the hole portion 182h forms a columnar space extending in the Z direction. The hole portion 182h inserts and accommodates the columnar temperature detector 80 from the +Z direction.

### Temperature Detector

The temperature detector 80 is accommodated in the hole portion 182h provided in the second fastening member 182. In the present embodiment, the temperature detector 80 is accommodated in the hole portion 182h and is fixed to the second fastening member 182 by, for example, a thermally conductive adhesive. The temperature detector 80 outputs a temperature detection result as an electric signal. The detection result of the temperature detector 80 can be input to a control device that performs temperature monitoring, or can be displayed on an external display. As the temperature detector 80, for example, a thermistor can be used. In the present embodiment, the temperature detector 80 has an elongated columnar shape such as a column or a prism, and an electric wire for output is connected to an end portion in the longitudinal direction (end portion in the Z direction) thereof.

The temperature detector 80 detects the temperature of the second fastening member 182. On the other hand, the head portion 185 of the second fastening member 182 is in contact with the metal component 60. The metal component 60 is in direct contact with the terminal portion 23. That is, the head portion 185 is indirectly connected to the terminal portion 23. Therefore, heat can be transferred between the terminal portion 23 and the metal component 60 and between the metal component 60 and the head portion 85. The temperature detector 80 indirectly detects the temperature of the terminal portion 23 by detecting the temperature of the second fastening member 182.

### B2. Method of Manufacturing Electrical Connection Unit

Next, a method of manufacturing the electrical connection unit 1 of the second embodiment will be described. Steps other than a first step described below are the same as those in the first embodiment.

### First Step

In the first step, the temperature detector 80 is inserted into the hole portion 182h of the second fastening member 182, and the temperature detector 80 is fixed in the hole portion 182h using a thermally conductive adhesive or the like. By this fixing, the second fastening member 182 and the temperature detector 80 are integrated. In the present embodiment, the temperature detector 80 is integrated with each of the plurality of second fastening members 182. In the second embodiment, after the first step, the second to fourth steps are performed similarly to the first embodiment. The first step may be performed after the fourth step. In the second step and the fourth step of the second embodiment, “first fastening member 81” and “second fastening member 82” in the description regarding the second step and the fourth step of the first embodiment may be replaced with “first fastening member 181” and “second fastening member 182”, respectively.

### B3. Advantages

In the present embodiment, the electrical connection unit 1 includes the first fastening member 181 that fixes the metal component 60 to the terminal portion 23 and the second fastening member 182 that fixes the metal component 60 to the bus bar 40. The temperature detector 80 is attached to the second fastening member 182.

According to such a constitution, the temperature detector 80 can be easily installed by using the second fastening member 182 as the fastening member for fixing the metal component 60 to the bus bar 40. Since the second fastening member 182 is in contact with the metal component 60 in contact with the terminal portion 23, the heat of the terminal portion 23 is transferred to the second fastening member 182, and the temperature of the terminal portion 23 can be indirectly detected by the temperature detector 80. Therefore, it is possible to reduce a burden on an operator who installs the temperature detector 80.

In the present embodiment, the second fastening member 182 includes the shaft portion 184 having a screw thread formed on the outer peripheral surface, and the head portion 185 having a larger diameter than the shaft portion 184. The head portion 185 has the hole portion 182h capable of accommodating the temperature detector 80. The bus bar 40 includes the attachment hole 41h in which a screw groove is formed on the inner peripheral surface and the shaft portion 184 can be screwed.

According to such a constitution, the metal component 60 can be fixed to the bus bar 40 only by screwing the shaft portion 184 into the attachment hole 41h. Since the hole portion 182h may be formed in the head portion 185 having a larger diameter than the shaft portion 184, the hole portion 182h can be easily provided. Since the temperature detector 80 only needs to be inserted into and fixed to the hole portion 182h formed in the head portion 185, the temperature detector 80 can be easily attached to the second fastening member 182.

In the present embodiment, the length T1 of the head portion 185 in the Z direction in which the shaft portion 184 extends and the length T4 of the head portion 185 in the direction perpendicular to the Z direction (the Y direction and the X direction) are larger than the thicknesses T2 and T3 of the metal component 60 and the bus bar 40.

According to such a constitution, a heat capacity larger than those of the metal component 60 and the bus bar 40 at the position fixed by the second fastening member 182 is secured in the head portion 185. Therefore, the head portion 185 can have a large heat storage function. A part of heat transferred to the metal component 60 can be stored (absorbed) at least temporarily by the head portion 185 of the second fastening member 182. According to this structure, it is possible to suppress occurrence of a large temperature rise in a part of the electrical connection unit 1 and/or an increase in thermal interference with the electronic component 20. Thermal characteristics (for example, heat dissipation or heat storage properties) of the electrical connection unit 1 can be improved.

### Third Embodiment

Next, a third embodiment will be described. The third embodiment is different from the first embodiment in not including a metal component described above. Constitutions other than those to be described below are the same as the constitutions of the first embodiment. In the third embodiment, an X direction is an example of a “first direction”, and a Y direction and a Z direction are examples of a “second direction”.

### C1 Bus Bar

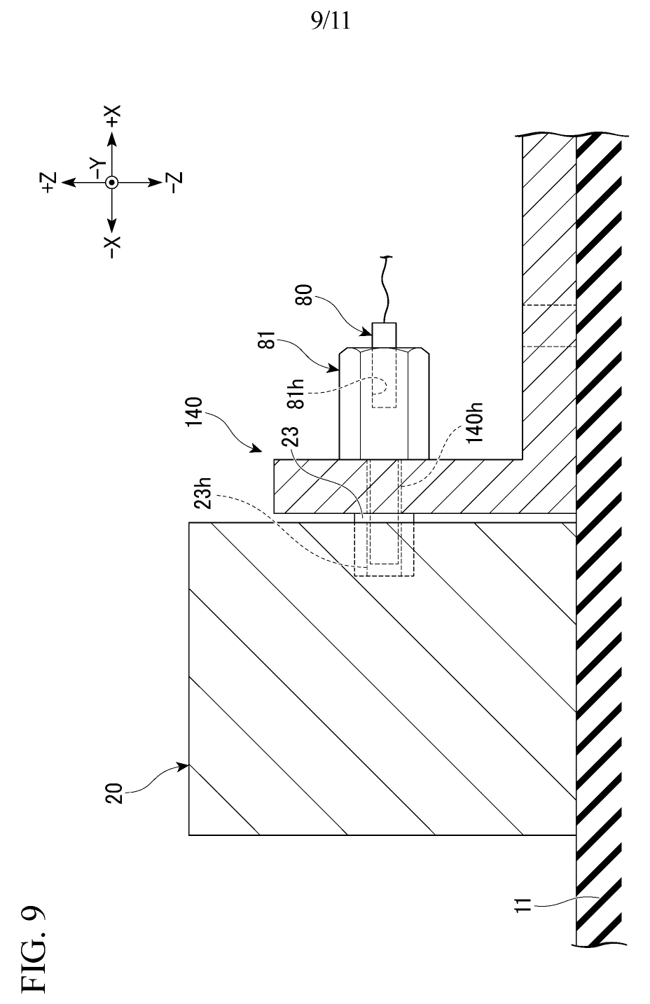

FIG. 9 is a cross-sectional view illustrating an electronic component, a bus bar, and a fastening member according to a third embodiment. A bus bar 140 is a wiring member included in an electrical connection unit 1, similarly to a bus bar 40 of the first embodiment. In the present embodiment, the bus bar 140 is an example of a “wiring member”.

The bus bar 140 is, for example, a wiring member that electrically connects a plurality of electronic components. Alternatively, the bus bar 140 may be a wiring member that connects one electronic component and the outside of the electrical connection unit 1. A structure for fixing the wiring member (bus bar 140) and the electronic component 30 (see FIG. 1) is the same as a structure for fixing the bus bar 140 and the electronic component 20. Hereinafter, only a structure for fixing the bus bar 140 and the electronic component 20 will be described.

The bus bar 140 is at least partially plate-shaped. In the present embodiment, the bus bar 140 has a plate shape over the entire bus bar 140. The bus bar 140 is fixed to the base member 11, for example. The bus bar 140 has a plate thickness T3.

The bus bar 140 has an attachment hole 140h through which the fastening member 81 passes. The attachment hole 140h is a through hole penetrating in the X direction. In the present embodiment, the bus bar 140 around the attachment hole 140h stands in the Z direction from the base member 11. The attachment hole 140h overlaps the attachment hole 23h of the terminal portion 23 in the +X direction.

### C2 Fastening Member

The fastening member 81 fixes the bus bar 140 and the electronic component 20. In the present embodiment, the electronic component 20 is an example of a “connection target component”. Hereinafter, for convenience of description, the fastening member 81 may be referred to as a “first fastening member 81”. The attachment hole 23h is an example of a “fastening hole portion”.

### First Fastening Member

The first fastening member 81 fixes the bus bar 140 to the terminal portion 23 of the electronic component 20. In the present embodiment, the first fastening member 81 has the same constitution as that of the first embodiment. The first fastening member 81 is engaged with the attachment hole 23h of the terminal portion 23 through the attachment hole 140h from the +Z direction. By this engagement, the bus bar 140 and the terminal portion 23 are physically and electrically connected.

### C3. Advantages

In the present embodiment, the electrical connection unit 1 includes the first fastening member 81 that fixes the bus bar 140 to the terminal portion 23. The temperature detector 80 is attached to the first fastening member 81.

According to such a constitution, even when the first fastening member 81 is used as the fastening member for fixing the bus bar 40 to the terminal portion 23, the temperature detector 80 can be easily installed. Since the first fastening member 81 is in contact with the bus bar 140 in contact with the terminal portion 23, the heat of the terminal portion 23 is transferred to the first fastening member 81, and the temperature of the terminal portion 23 can be indirectly detected by the temperature detector 80. Therefore, it is possible to reduce a burden on an operator who installs the temperature detector 80.

Furthermore, a heat capacity larger than that of the bus bar 140 at a position fixed by the first fastening member 81 is secured by the first fastening member 81. Therefore, a part of the heat transmitted through the bus bar 140 can be stored (absorbed) at least temporarily by the first fastening member 81.

### Fourth Embodiment

Next, a fourth embodiment will be described. The fourth embodiment is different from the first embodiment in a structure in which a temperature detector is attached. Constitutions other than those to be described below are the same as the constitutions of the first embodiment. In the fourth embodiment, a Z direction is an example of a “first direction”.

### D1. Constitution of Fastening Member

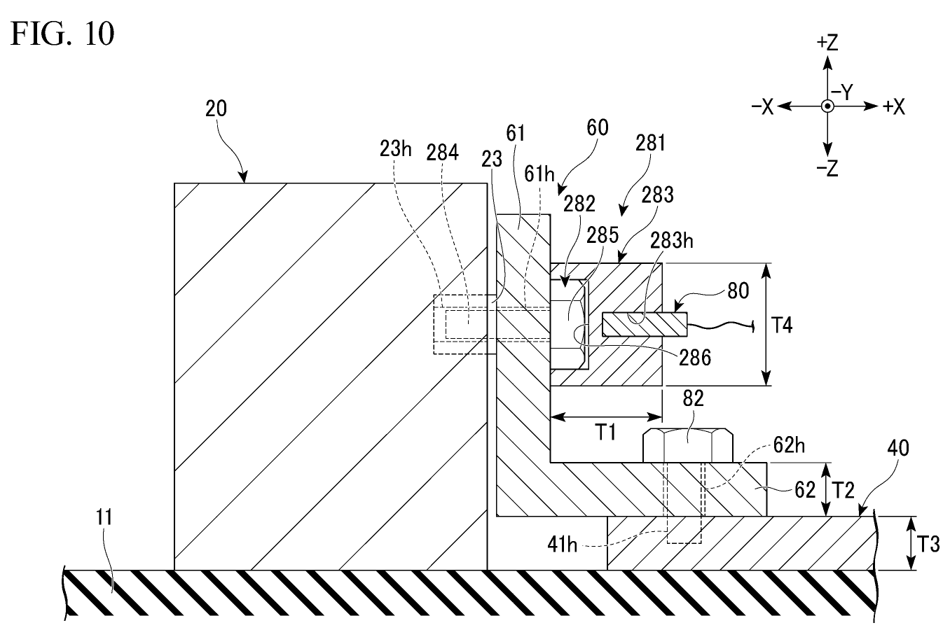

FIG. 10 is a cross-sectional view illustrating an electronic component, a metal component, a bus bar, and a fastening member according to the fourth embodiment. A fastening member 281 fixes a metal component 60 and an electronic component 20, and a fastening member 82 fixes the metal component 60 and the bus bar 40. In the present embodiment, the metal component 60 is an example of a “wiring member”, and the electronic component 20 is an example of a “connection target component”. The attachment hole 23h is an example of a “fastening hole portion”.

Hereinafter, for convenience of description, the fastening member 281 may be referred to as a “first fastening member 281”. In addition, the fastening member 82 may be referred to as a “second fastening member 82”. Note that the fastening member that fixes the wiring member (second metal component 70) and the connection target component (electronic component 30) has the same constitution as the fastening member 281, and thus description thereof is omitted.

### First Fastening Member

The first fastening member 281 fixes the first portion 61 of the metal component 60 to the terminal portion 23 of the electronic component 20. In the present embodiment, the first fastening member 281 includes a fastening member body 282 and a metal cap portion 283.

### Fastening Member Body

In the present embodiment, the fastening member body 282 is a bolt. The fastening member body 282 has the same constitution (shaft portion 284 having a screw thread formed on an outer peripheral surface, and head portion 285 having a larger diameter than shaft portion 284) as the second fastening member 82. The fastening member body 282 is engaged with the attachment hole 23h of the terminal portion 23 through the first attachment hole 61h of the first portion 61 from the +X direction. By this engagement, the first portion 61 of the metal component 60 and the terminal portion 23 are physically and electrically connected.

### Metal Cap Portion

The metal cap portion 283 is attached to the head portion 285 of the fastening member body 282. For example, the material of the metal cap portion 283 can be the same metal material as that of the fastening member body 282, but may be a different metal material. Examples of the material of the metal cap portion 283 may include copper, a copper alloy, aluminum, an aluminum alloy, steel, stainless steel, magnesium, a magnesium alloy, titanium, and a titanium alloy. The metal cap portion 283 has a hole portion 283h capable of accommodating the temperature detector 80. The hole portion 283h has the same shape as the hole portion 81h of the first embodiment described above. The hole portion 283h extends in the X direction and opens in the +X direction.

In the present embodiment, the metal cap portion 283 has an attachment portion 286 capable of accommodating the head portion 285 of the fastening member body 282. The attachment portion 286 is recessed from the -X direction to the +X direction. In the present embodiment, the inner peripheral surface of the attachment portion 286 viewed from the X direction has a shape corresponding to the contour of the outer peripheral surface of the head portion 285 of the fastening member body 282 viewed from the X direction. The head portion 285 of the fastening member body 282 is press-fitted into the attachment portion 286. In the present embodiment, the metal cap portion 283 is moved from the +X direction to the -X direction to accommodate the head portion 285 of the fastening member body 282 in the attachment portion 286. When the head portion 285 of the fastening member body 282 is accommodated in the attachment portion 286, the opening edge of the attachment portion 286 comes into contact with the metal component 60. As described above, the metal cap portion 283 has a larger volume and a larger heat capacity than the head portion 285 of the fastening member body 282.

In the present embodiment, for example, the contour of the outer peripheral surface of the head portion 285 of the fastening member body 282 has a hexagonal shape. Therefore, the contour of the inner peripheral surface of the attachment portion 286 also has a hexagonal shape. The case where the metal cap portion 283 is attached to the fastening member body 282 by press-fitting the head portion 285 of the fastening member body 282 into the attachment portion 286 has been described. However, the constitution is not limited to the constitution in which the metal cap portion 283 is press-fitted into the fastening member body 282. For example, the attachment portion 286 of the metal cap portion 283 and the head portion 285 of the fastening member body 282 may be fixed using a thermally conductive adhesive.

### D2. Advantages

In the present embodiment, the fastening member 281 includes the fastening member body 282 having the shaft portion 284 in which a screw thread is formed on an outer peripheral surface and the head portion 285 having a larger diameter than the shaft portion 284. The fastening member 281 further includes the metal cap portion 283 attached to the head portion 285 of the fastening member body 282 and having the hole portion 283h capable of accommodating the temperature detector 80.

According to such a constitution, the heat of the terminal portion 23 is transferred from the fastening member body 282 to the metal cap portion 283. The heat of the terminal portion 23 is further transferred from the first portion 61 of the metal component 60 to the metal cap portion 283 via the head portion 285 of the fastening member body 282. The temperature detector 80 is accommodated in the hole portion 283h of the metal cap portion 283, and the temperature rise of the metal cap portion 283 due to the heat of the terminal portion 23 is detected by the temperature detector 80. On the other hand, since it is only necessary to attach the metal cap portion 283 to which the temperature detector 80 is attached to the head portion 285 of the fastening member body 282 engaged with the attachment hole 23h of the terminal portion 23, the temperature detector 80 can be easily attached. Therefore, it is possible to reduce the burden on the operator.

Furthermore, in the above embodiment, since the metal cap portion 283 has a large heat capacity, a part of heat transferred through the metal component 60 and the bus bar 40 can be stored (absorbed) at least temporarily by the metal cap portion 283 and the head portion 285 of the fastening member body 282.

### Fifth Embodiment

Next, a fifth embodiment will be described. The fifth embodiment is different from the first embodiment in that a shape of a terminal portion of an electronic component is different. Constitutions other than those to be described below are the same as the constitutions of the first embodiment. In the present embodiment, a bus bar 40 is an example of a “wiring member”, and an electronic component 20 is an example of a “connection target component”. In the present embodiment, a fastening member for fixing the bus bar 40 and the electronic component 20 will be described. The structure for fixing the bus bar 40 and the electronic component 30 (see FIG. 1) is the same as the structure for fixing the bus bar 40 and the electronic component 20, and thus the description thereof is omitted. In the present embodiment, a Z direction is an example of a “first direction”.

### E1 Terminal Portion

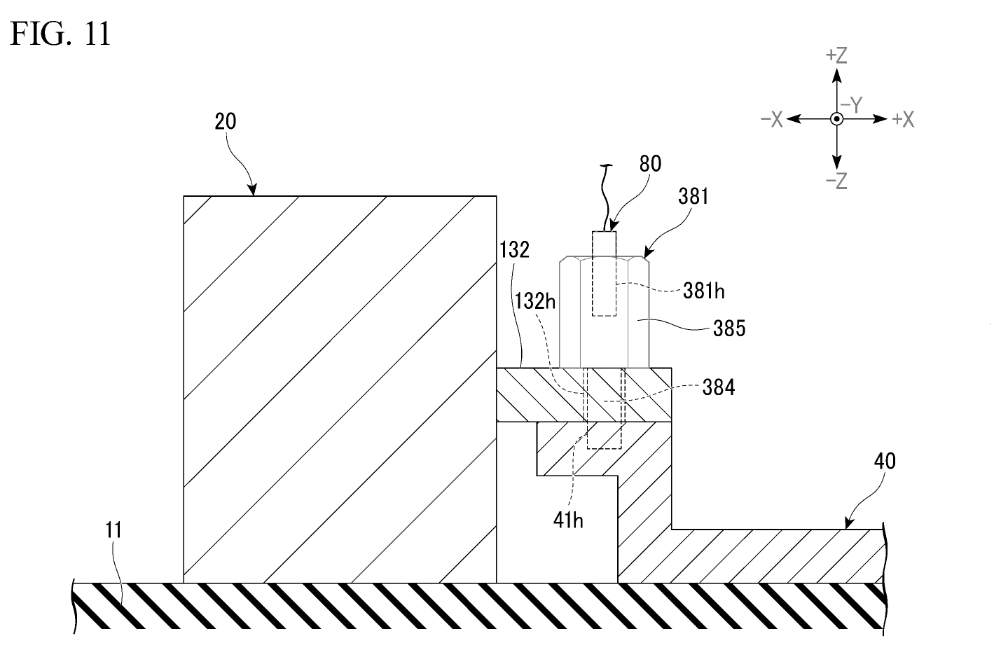

FIG. 11 is a cross-sectional view illustrating an electronic component, a bus bar, and a fastening member according to the fifth embodiment. The electronic component 20 has a terminal portion 132. The terminal portion 132 is an electrical connection portion exposed to the outside of the case of the electronic component 20. The terminal portion 132 is disposed at a position away from the base member 11 in the +Z direction. In the present embodiment, the first terminal portion 23A and the second terminal portion 23B are provided at end portions on the +X direction side of the first electronic component 20. The terminal portion 132 has an attachment hole 132h. The attachment hole 132h is a through hole penetrating the terminal portion 132 in the Z direction. The terminal portion 132 extends in the +X direction from the case of the electronic component 20. The terminal portion 132 of the present embodiment has a flat plate shape with the Z direction as a thickness direction. In the present embodiment, the thickness of the terminal portion 132 in the Z direction is the same as the thickness of the bus bar 40 in the Z direction, but the thickness of the terminal portion 132 in the Z direction and the thickness of the bus bar 40 in the Z direction may be different.

### E2 Bus Bar

The bus bar 40 of the present embodiment has an attachment hole 41h. In the present embodiment, the bus bar 40 around the attachment hole 41h is disposed so as to be in contact with the terminal portion 132 of the electronic component 20 from the Z direction. In the present embodiment, the bus bar 40 is in contact with the terminal portion 132 from the -Z direction. The bus bar 40 of the present embodiment is disposed along the base member 11 and is separated from the base member 11 in the +Z direction only around the attachment hole 41h. The arrangement of the terminal portion 132 and the bus bar 40 at the contact portion is not limited to the above arrangement. In the present embodiment, the attachment hole 41h is an example of a “fastening hole portion”.

### E3 Fastening Member

The fastening member 381 fixes the bus bar 40 and the terminal portion 132 of the electronic component 20. The fastening member 381 of the present embodiment is an example of a “first fastening member”. In the present embodiment, the fastening member 381 is a metal bolt having a shaft portion 384 and a head portion 385.

The shaft portion 384 has a columnar shape extending in the X direction and has a screw thread formed on the outer peripheral surface. In the present embodiment, the attachment hole 41h of the bus bar 40 has a spiral screw groove on the inner peripheral surface. The shaft portion 384 can be screwed into the attachment hole 41h of the bus bar 40. The attachment hole 41h may be a hole that does not have a screw groove and is engaged with the shaft portion 384 of the fastening member 381. The constitution is not limited to the constitution in which the fastening member 381 engages with the attachment hole 41h, and may include a case where fastening is performed by combining a component (for example, an engagement member such as a nut) different from the bus bar 40.

The details of the fastening member 381 are, for example, similar to those of the second fastening member 182 of the second embodiment except that the connection target components to be connected are different. In the description regarding the fastening member 381, “shaft portion 84”, “head portion 85”, and “hole portion 182h” in the description regarding the second fastening member 182 described above may be replaced with “shaft portion 384”, “head portion 385”, and “hole portion 381h”, respectively.

### E4. Advantages

In the present embodiment, the fastening member 381 includes the shaft portion 384 having a screw thread formed on the outer peripheral surface, and the head portion 385 having a larger diameter than the shaft portion 384. The head portion 385 has the hole portion 381h capable of accommodating the temperature detector 80. The terminal portion 132 of the electronic component 20 and the bus bar 40 have a plate shape. The terminal portion 132 is fixed to the bus bar 40 using the fastening member 381.

According to such a constitution, the heat of the terminal portion 132 is transferred to the head portion 385 of the fastening member 381. The temperature detector 80 is accommodated in the hole portion 381h of the head portion 385, and a temperature rise of the head portion 385 due to heat of the terminal portion 132 is detected by the temperature detector 80. Therefore, even when the terminal portion 132 has a plate shape, the temperature detector 80 can be easily attached. Therefore, it is possible to reduce the burden on the operator.

Furthermore, in the above embodiment, since the head portion 385 has a large heat capacity, a part of the heat transferred through the bus bar 40 can be stored (absorbed) at least temporarily by the head portion 385.

Several embodiments and modifications have been described above. However, the embodiments and the modifications are not limited to the examples described above. For example, two or more embodiments or modifications described above may be implemented in combination with each other. In addition, the embodiments and modifications described above are merely examples. The electrical connection unit 1 is not limited to the constitution including all the dimensional relationships described above, and may have a constitution including only a part of the dimensional relationships described above.

For example, the method of fixing the temperature detector 80 is not limited to using a thermally conductive adhesive. For example, the temperature detector may be fixed by being press-fitted into the hole portion.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

### REFERENCE SIGNS LIST

1 Electrical connection unit

10 Housing

11 Base member

11a Support surface

11h Attachment hole

11s Flat surface

12 Cover member

20, 30 Electronic component

21, 31 Case

21a Insulating wall

21e1 End

21e2 End

22, 32 Body portion

23, 33 Terminal portion

23h, 33h Attachment hole

24, 34 Attachment portion

24h, 34h Attachment hole

29, 39 Fastening member

32 Body portion

40, 140 Bus bar

40s Plate surface

41 First connection portion

41h, 42h Attachment hole

42 Second connection portion

43 Extension portion

43h Attachment hole

51 Fixing member

52 Engagement member

60, 70 Metal component

61, 71 First portion

61h, 71h First attachment hole

62, 72 Second portion

62h, 72h Second attachment hole

80 Temperature detector

81, 82, 91, 92, 181, 182, 281, 381 Fastening member

81h, 91h, 182h, 283h, 381h Hole portion

84, 94, 184, 284, 384 Shaft portion

85, 95, 185, 285, 385 Head portion

132 Terminal portion

132h Attachment hole

140h Attachment hole

282 Fastening member body

283 Metal cap portion

286 Attachment portion

MP Placement table

SA First assembly

SB Second assembly

What is claimed is:

1. An electrical connection unit comprising:
a wiring member;
a connection target component to which the wiring member is electrically connected;
a fastening member that comes into contact with the wiring member and fixes the wiring member to the connection target component; and
a temperature detector that is attached to the fastening member and detects a temperature.

2. The electrical connection unit according to claim 1, wherein
the connection target component is an electronic component having a terminal portion, and
the fastening member is a first fastening member that fixes the wiring member to the terminal portion.

3. The electrical connection unit according to claim 1, wherein
the wiring member is a metal component connected to an electronic component having a terminal portion,
the connection target component is a bus bar, and
the fastening member is a second fastening member that fixes the metal component to the bus bar.

4. The electrical connection unit according to claim 1, wherein
the fastening member includes a shaft portion in which a screw thread is formed on an outer peripheral surface, and a head portion having a hole portion capable of accommodating the temperature detector and having a larger diameter than the shaft portion, and
the connection target component includes a fastening hole portion in which a screw groove is formed in an inner peripheral surface to be capable of screwing the shaft portion.

5. The electrical connection unit according to claim 1, wherein
the fastening member includes:
a fastening member body including a shaft portion in which a screw thread is formed on an outer peripheral surface, and a head portion having a larger diameter than the shaft portion; and
a metal cap portion attached to the head portion of the fastening member body and having a hole portion capable of accommodating the temperature detector.

6. The electrical connection unit according to claim 4, wherein
a length of the head portion in a first direction in which the shaft portion extends and a length of the head portion in a second direction perpendicular to the first direction are larger than a thickness of the wiring member.
